(19) United States
(12) Patent Application Publication
(10) Pub. No.: US 2018/0350291 A1
(43) Pub. Date: Dec. 6, 2018

(54) PIXEL STRUCTURE

(71) Applicant: AU Optronics Corporation, Hsin-chu (TW)

(72) Inventors: Tsung-Tien WU, Hsin-chu (TW); Kang-Hung Liu, Hsin-Chu (TW); Norio Sugiura, Hsin-Chu (TW)

(21) Appl. No.: 15/951,429

(22) Filed: Apr. 12, 2018

(30) Foreign Application Priority Data
Jun. 6, 2017 (TW) 106118628

(51) Int. Cl. G09G 3/20; G02B 5/20; H05B 33/08; H01L 29/40

(52) U.S. Cl. CPC G09G 3/2003; G02B 5/20; G09G 2310/0264; H01L 29/40; G09G 2300/0452; H05B 33/0806

(57) ABSTRACT

A pixel structure is provided. The pixel structure includes a first sub-pixel. The first sub-pixel includes a first yellow light-emitting diode (LED), a first blue LED, and a first color filter. The first color filter is disposed above the first yellow LED and the first blue LED. The first color filter is configured to pass light of a first color.

### BACKGROUND

### Technical Field

The present disclosure relates to a pixel structure, and in particular, to a pixel structure using a light-emitting diode (LED).

### Related Art

An LED is a semiconductor electronic component widely applied to display technologies for the moment. A bias voltage of the LED is logarithm relevant to a forward current of the LED. A slight difference in the voltage of a power supply or the bias voltage of the LED makes the current experience a relatively large change due to the discreteness of production processes. However, the luminosity of the LED is relatively directly connected to the current. The current change causes the brightness of the LED to shift, causing the phenomenon of color cast. Therefore, how to implement an LED pixel structure that can improve the color cast phenomenon is one of subjects that the industry is working on for the moment.

### SUMMARY

The present disclosure relates to a pixel structure using an LED, so that the phenomenon of color cast can be improved.

According to an aspect of the present disclosure, a pixel structure is provided. The pixel structure includes a first sub-pixel. The first sub-pixel includes a first yellow LED, a first blue LED, and a first color filter. The first color filter is disposed above the first yellow LED and the first blue LED, where the first color filter is configured to pass light of a first color.

To better understand the foregoing and other aspects of the present disclosure, embodiments accompanied with figures are described in detail below.

### BRIEF DESCRIPTION OF THE DRAWINGS

FIG. 1 is a schematic diagram of a pixel structure according to an embodiment of the present disclosure;

FIG. 2 is a schematic diagram of wavelength changes on a CIE 1931 xy chromaticity diagram;

FIG. 3 is a schematic diagram of a pixel structure according to an embodiment of the present disclosure;

FIG. 4A is a schematic diagram of a pixel structure according to an embodiment of the present disclosure;

FIG. 4B is a circuit diagram corresponding to FIG. 4A;

FIG. 5A is a schematic diagram of a pixel structure according to an embodiment of the present disclosure;

FIG. 5B is a circuit diagram corresponding to FIG. 5A;

FIG. 6A is a schematic diagram of a pixel structure according to an embodiment of the present disclosure;

FIG. 6B is a circuit diagram corresponding to FIG. 6A;

FIG. 7A is a schematic diagram of a pixel structure according to an embodiment of the present disclosure;

FIG. 7B is a circuit diagram corresponding to FIG. 7A;

FIG. 8A is a schematic diagram of a pixel structure according to an embodiment of the present disclosure; and

FIG. 8B is a circuit diagram corresponding to FIG. 8A.

### DETAILED DESCRIPTION

It will be understood that when an element such as a layer, film, region, or substrate is referred to as being “on” or “connected to” another element, it can be directly on or connected to the other element or intervening elements may also be present. In contrast, when an element is referred to as being “directly on” or “directly connected to” another element, there are no intervening elements present. As used herein, “connected” may refer to a physical and/or electrical connection. Furthermore, “electrically connected” or “coupled” may be other elements between two elements.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the invention, and will not be interpreted in an idealized or overly formal sense unless expressly so defined herein.

Display panels are widely used in a plurality of types of consumer electronic products, such as computer screens, mobile phones, and televisions. A display panel includes a plurality of pixels, and each of the pixels may include a plurality of sub-pixels, for example, three sub-pixels in total: red, green, and blue sub-pixels. In a display panel using an LED, sub-pixels, for example, may respectively use LEDs capable of emitting light rays with different wavelengths, such as a red LED, a green LED, and a blue LED. However, when currents driving the LEDs are different, not only light intensity emitted by the LEDs changes, but also optical wavelengths emitted by the LEDs may possibly shift. Consequently, the phenomenon of color cast may occur on the display panel. The present disclosure provides a pixel structure, to mitigate the problem of color cast of an LED.

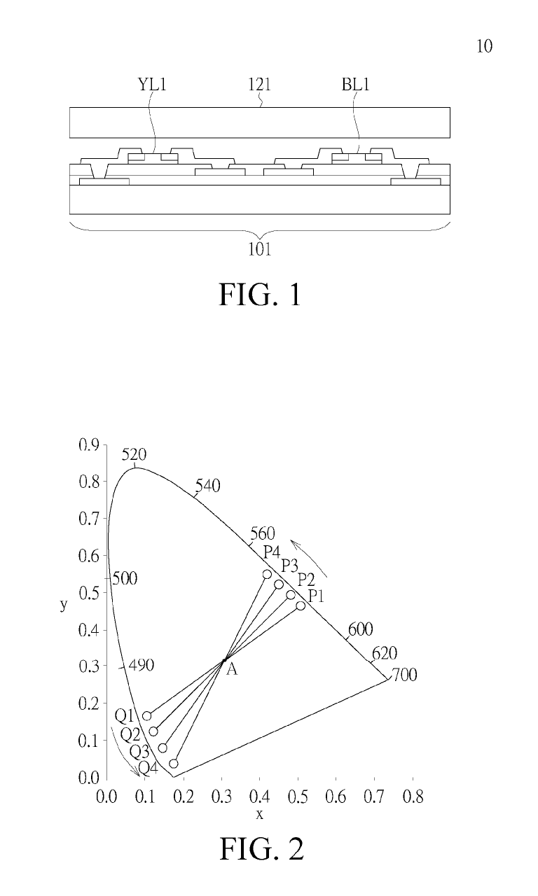

FIG. 1 is a schematic diagram of a pixel structure according to an embodiment of the present disclosure. A pixel structure 10 includes a first sub-pixel 101. The first sub-pixel 101 includes a first yellow LED YL1, a first blue LED BL1, and a first color filter 121. The first color filter 121 is disposed above the first yellow LED YL1 and the first blue LED BL1, and the first color filter 121 is configured to pass light of a first color.

In the pixel structure of the present disclosure, when the first sub-pixel 101 uses the first yellow LED YL1 and the first blue LED BL1, wavelength shifting attributes of the two LEDs, for example, may be shifting towards a same direction. In this way, white light of a same color temperature can be formed by means of mixture, thereby mitigating the problem of color cast of the LEDs under operation by using different currents. For example, when an optical wavelength emitted by the first yellow LED YL1 shifts towards a short wavelength, an optical wavelength emitted by the first blue LED BL1 shifts towards the short wavelength. When the optical wavelength emitted by the first yellow LED YL1 shifts towards a long wavelength, the optical wavelength emitted by the first blue LED BL1 shifts towards the long wavelength. The first color filter 121 may determine a color displayed by the first sub-pixel 101. For example, the first color filter 121 may be configured to pass a light ray of a red color, and the first sub-pixel 101 may be used as a red sub-pixel.

FIG. 2 is a schematic diagram of wavelength changes on a CIE 1931 xy chromaticity diagram. As shown in FIG. 2, a curved boundary of a gamut corresponds to monochromatic light. In the figure, the wavelength of the monochromatic light uses a nanometer (nm). In the figure, point A represents the position of white light. Points P1 to P4 represent yellow light (e.g. the wavelength range is approximately 590 nm to 570 nm). Points Q1 to Q4 represent blue light (e.g. the wavelength range is approximately 490 nm to 450 nm). As shown in FIG. 2, yellow light at point P1 may be mixed with blue light at point Q1 to generate white light at point A Similarly, the white light at the point A may be generated by mixing yellow light at point P2 with blue light at point Q2, by mixing yellow light at point P3 with blue light at point Q3, or by mixing yellow light at point P4 with blue light at point Q4. The direction from the point P1 to the point P4 represents that the wavelength of the yellow light decreases, and the direction from the point Q1 to the point Q4 represents that the wavelength of the blue light decreases.

Therefore, a proper doping concentration is controlled by manufacturing the first yellow LED YL1 and the first blue LED BL1 by selecting a proper semiconductor material, and/or by properly controlling driving currents of the first yellow LED YL1 and the first blue LED BL1, the optical wavelength emitted by the first blue LED BL1 shifts towards the short wavelength (for example, from the point Q1 to the point Q4) when the optical wavelength emitted by the first yellow LED YL1 shifts towards the short wavelength (for example, from the point P1 to the point P4), and then light of a mixed color emitted by the first yellow LED YL1 and the first blue LED BL1 may be kept at the position of the white light at the point A in FIG. 2. That is, even if the first yellow LED YL1 and the first blue LED BL1 respectively have cases of color cast, light of a mixed color generated by the two LEDs can keep same white light, so as to avoid the problem of color cast.

A semiconductor material used by the first yellow LED YL1, for example, is GaAsP, AlGaInP, or nitrogen doped with GaP (GaP:N). A semiconductor material used by the first blue LED BL1, for example, is ZnSe, InGaN, or SiC.

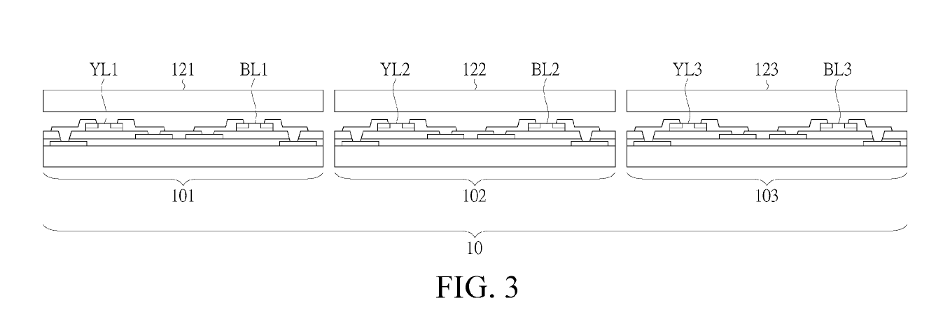

FIG. 3 is a schematic diagram of a pixel structure according to an embodiment of the present disclosure. A pixel structure 10 includes a first sub-pixel 101, a second sub-pixel 102, and a third sub-pixel 103. The second sub-pixel 102 includes a second yellow LED YL2, a second blue LED BL2, and a second color filter 122. The second color filter 122 is disposed above the second yellow LED YL2 and the second blue LED BL2, and the second color filter 122 is configured to pass light of a second color, and the second color is different from the first color. For example, the first color filter 121 may pass red light, the second color filter 122 may pass green light, the first sub-pixel 101 is used as a red sub-pixel, and the second sub-pixel 102 is used as a green sub-pixel.

The third sub-pixel 103 includes a third yellow LED YL3, a third blue LED BL3, and a third color filter 123. The third color filter 123 is disposed above the third yellow LED YL3 and the third blue LED BL3. The third color filter 123 is configured to pass light of a third color. The third color is different from the first color, and is different from the second color. For example, the third color filter 123 may pass blue light, and the third sub-pixel 103 is used as a blue sub-pixel. The pixel structure 10 shown in the embodiment of FIG. 3 includes the first sub-pixel 101 (e.g. red sub-pixel), the second sub-pixel 102 (e.g. green sub-pixel), and the third sub-pixel 103 (e.g. blue sub-pixel). Therefore, the pixel structure 10 can be used in a display panel to display color image data.

In an embodiment, the third sub-pixel 103 is used as a blue sub-pixel, and the third sub-pixel 103 may include only the third blue LED BL3. That is, the third sub-pixel 103 may not include the third yellow LED YL3, and may either not include the color filter 123, and the single third blue LED BL3 is used as the blue sub-pixel. In this way, the hardware costs can be reduced, and the quantity of used color filters can be reduced.

A plurality of embodiments is described below with respect to a circuit connection line between a first yellow LED YL1 and the first blue LED BL1. In the following embodiments, the color filter 121 is omitted to enable related circuit diagrams to be clearly drawn.

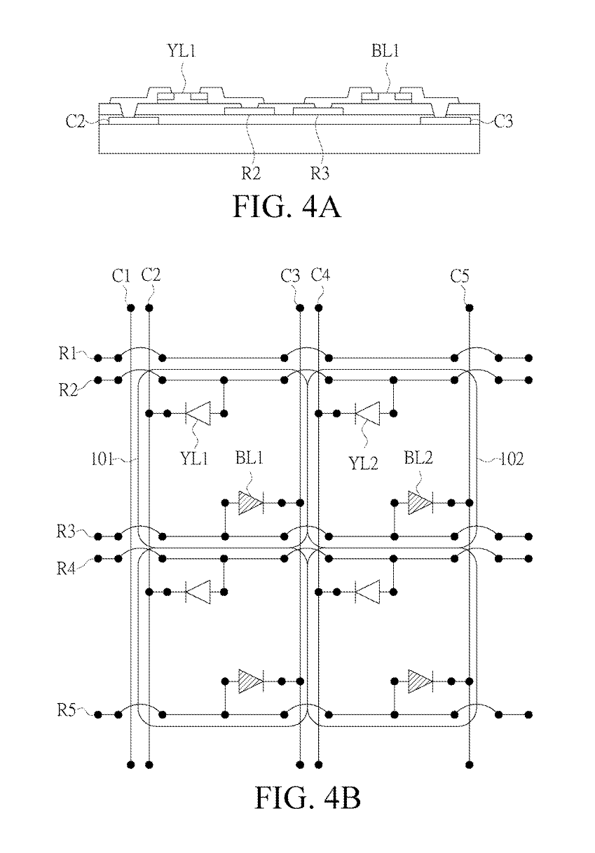

FIG. 4A is a schematic diagram of a pixel structure according to an embodiment of the present disclosure, and FIG. 4B is a circuit diagram corresponding to FIG. 4A. As shown in FIG. 4A, a first yellow LED YL1 and the first blue LED BL1 are respectively independently controlled, and driving currents of them can be respectively adjusted. Referring to FIG. 4B at the same time, an anode end of the first yellow LED YL1 is coupled to a row electrode signal line R2, and a cathode end is coupled to a column electrode signal line C2; an anode end of the first blue LED BL1 is coupled to a row electrode signal line R3, and a cathode end is coupled to a column electrode signal line C3. That is, the first sub-pixel 101 uses four control signals to determine a driving current of an LED inside the first sub-pixel 101. The four control signals include the row electrode signal line R2, the row electrode signal line R3, the column electrode signal line C2, and the column electrode signal line C3. FIG. 4B shows four sub-pixels. The structures of the remaining three sub-pixels are similar to that of the first sub-pixel 101, and the sub-pixels respectively control a driving current of each diode. In the accompanying drawings of the present specification, a hollow triangle is used to represent a yellow LED, and a diagonal triangle is used to represent a blue LED.

Driving currents provided by the four control signals (e.g. the row electrode signal line R2, the row electrode signal line R3, the column electrode signal line C2, and the column electrode signal line C3) should enable an optical wavelength emitted by the first blue LED BL1 to shift towards a short wavelength when an optical wavelength emitted by the first yellow LED YL1 shifts towards the short wavelength. For example, if according to the attributes of the selected semiconductor materials, the first yellow LED YL1 shifts towards the short wavelength with the decrease of the current and the first blue LED BL1 shifts towards the short wavelength with the increase of the current, when the driving current provided to the first blue LED BL1 increases, the driving current provided to the first yellow LED YL1 should decrease, so that the first yellow LED YL1 and the first blue LED BL1 both present the phenomenon of shifting towards the short wavelength, as shown in FIG. 2. In this way, stable white light can be generated by means of mixture.

In the embodiment shown in FIG. 4B, a second sub-pixel 102 is adjacent to the first sub-pixel 101. The first sub-pixel 101 and the second sub-pixel 102, for example, may use color filters of different colors. The second sub-pixel 102 includes a second yellow LED YL2 and a second blue LED BL2. In this embodiment, an anode end of the first blue LED BL1 is coupled to an anode end of the second blue LED BL2. That is, the first blue LED BL1 and the second blue LED BL2 may be coupled to the same row electrode signal line R3. In addition, the anode end of the first yellow LED YL1 is coupled to the anode end of the second yellow LED YL2. That is, the first yellow LED YL1 and the second yellow LED YL2 may be coupled to the same row electrode signal line R2.

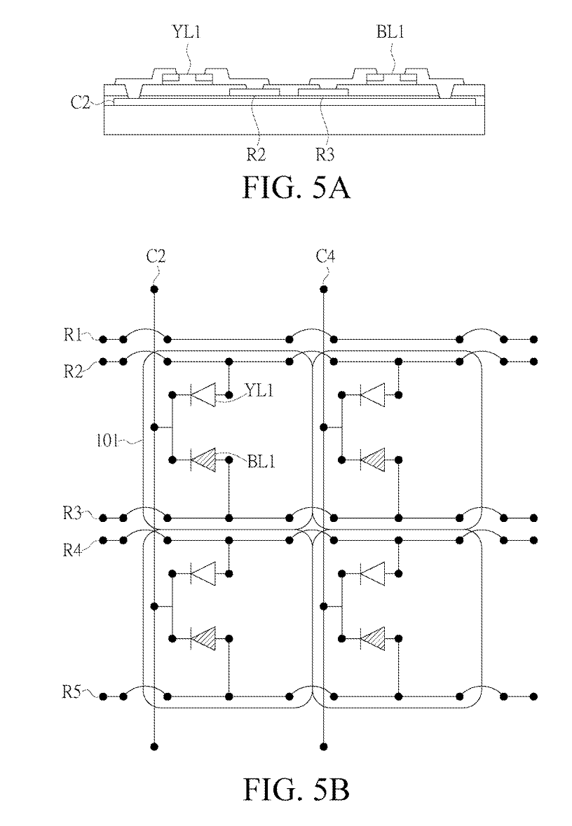

FIG. 5A is a schematic diagram of a pixel structure according to an embodiment of the present disclosure, and FIG. 5B is a circuit diagram corresponding to FIG. 5A. In this embodiment, a cathode end of the first yellow LED YL1 is coupled to a cathode end of the first blue LED BL1. That is, two LEDs share a substantially same cathode voltage level. Specifically, the anode end of the first yellow LED YL1 is coupled to the row electrode signal line R2, the anode end of the first blue LED BL1 is coupled to the row electrode signal line R3, and the cathode end of the first yellow LED YL1 and the cathode end of the first blue LED BL1 are both coupled to the column electrode signal line C2.

In this embodiment, because the cathode ends of the two LEDs share one signal line, the circuit area can be reduced. In addition, the first yellow LED YL1 and the first blue LED BL1 are respectively driven (e.g. different row electrode signal lines R2 and R3 provide driving signals). In this embodiment, the driving circuit may be controlled to avoid formation of the phenomenon of reverse bias of a diode. For example, the row electrode signal line R2 and the row electrode signal line R3 may approximately keep the trend that voltages increase or decrease together, to avoid causing reverse bias of a diode. Therefore, for the selected first yellow LED YL1 and first blue LED BL1, the two LEDs should have the trend of shifting towards a same wavelength direction because they are affected by the color cast effect of currents. For example, when the driving currents increase, light emitted by the first yellow LED YL1 and light emitted by the first blue LED BL1 both shift towards a short wavelength. The first yellow LED YL1 and the first blue LED BL1 may be enabled, by selecting a proper semiconductor material and controlling the doping concentration, to have the trend of shifting towards the same wavelength direction when they are affected by the color cast effect of currents.

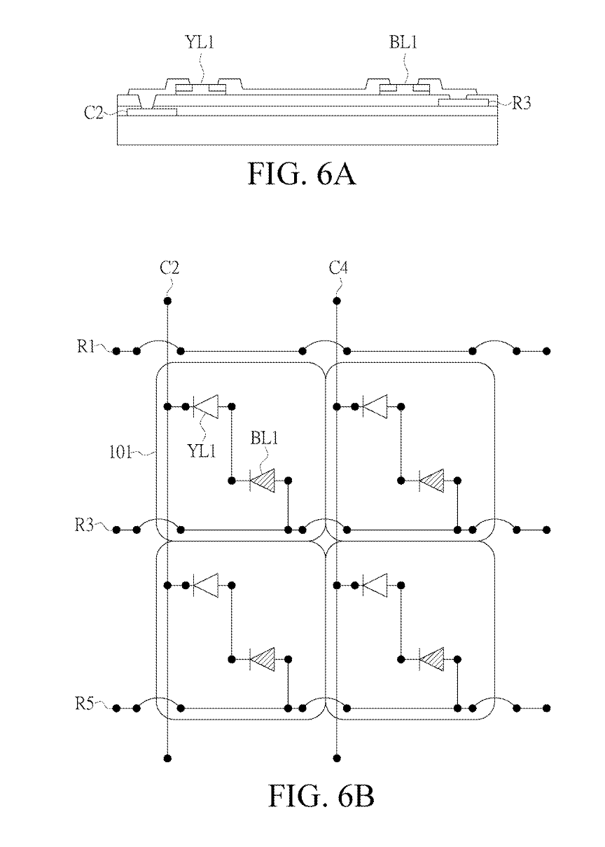

FIG. 6A is a schematic diagram of a pixel structure according to an embodiment of the present disclosure, and FIG. 6B is a circuit diagram corresponding to FIG. 6A. In this embodiment, a first yellow LED YL1 is connected in series to a second blue LED BL1. Specifically, an anode end of the first yellow LED YL1 is coupled to a cathode end of the first blue LED BL1, a cathode end of the first yellow LED YL1 is coupled to a column electrode signal line C2, and an anode end of the first blue LED BL1 is coupled to a row electrode signal line R3. In this embodiment, only two control signal lines are needed to determine the driving current for the first sub-pixel 101, so that the circuit complexity can be reduced more effectively.

In this embodiment, because the first yellow LED YL1 is connected in series to the first blue LED BL1 and currents passing the two LEDs are substantially the same, the two LEDs should have the trend of shifting towards a same wavelength direction because they are affected by the color cast effect of currents. As stated above, the first yellow LED YL1 and the first blue LED BL1 may be enabled, by selecting a proper semiconductor material and controlling the doping concentration, to have the trend of shifting towards the same wavelength direction when they are affected by the color cast effect of currents, thereby implementing the function of compensating for the light emitting frequency shifting phenomenon generated by the LEDs due to different sizes of currents.

An example drawn in FIG. 6B is that the anode end of the first yellow LED YL1 is coupled to the cathode end of the first blue LED BL1. In another embodiment, connection in series may alternatively be that the cathode end of the first yellow LED YL1 is coupled to the anode end of the first blue LED BL1.

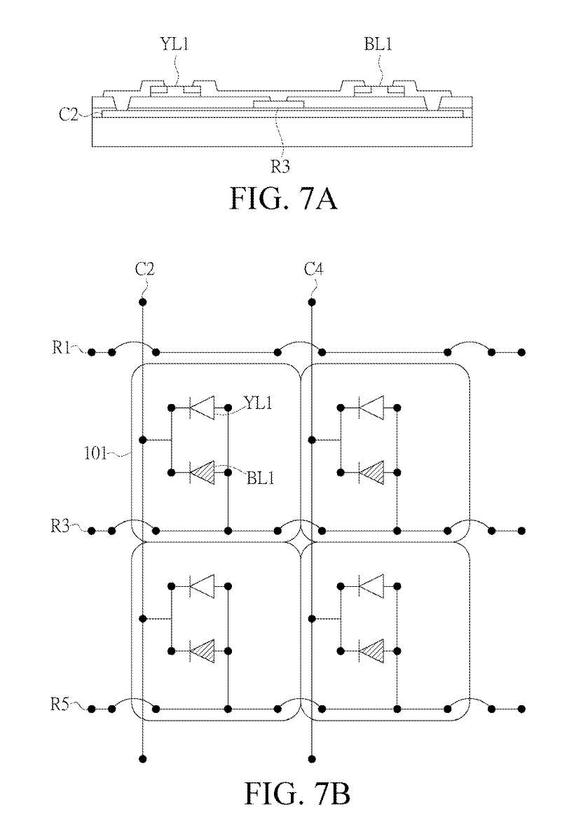

FIG. 7A is a schematic diagram of a pixel structure according to an embodiment of the present disclosure, and FIG. 7B is a circuit diagram corresponding to FIG. 7A. In this embodiment, a first yellow LED YL1 is connected in parallel to a second blue LED BL1. Specifically, a cathode end of the first yellow LED YL1 and a cathode end of the first blue LED BL1 are both coupled to a column electrode signal line C2, and an anode end of the first yellow LED YL1 and an anode end of the first blue LED BL1 are both coupled to a row electrode signal line R3. In this embodiment, only two control signal lines are needed to determine the driving current for the first sub-pixel 101, so that the circuit complexity can be reduced.

In this embodiment, because the first yellow LED YL1 is connected in parallel to the first blue LED BL1 and cross voltages of the two LEDs are substantially the same, the two LEDs should have the trend of shifting towards a same wavelength direction because they are affected by the color cast effect of currents. As stated above, the first yellow LED YL1 and the first blue LED BL1 may be enabled, by selecting a proper semiconductor material and controlling the doping concentration, to have the trend of shifting towards the same wavelength direction when they are affected by the color cast effect of currents. The advantage of using the structure that two LEDs are connected in parallel is: when one of the LEDs (such as the first yellow LED YL1) is broken, the other LED (such as the first blue LED BL1) still can emit light by using current, so that the first sub-pixel 101 still can display image data.

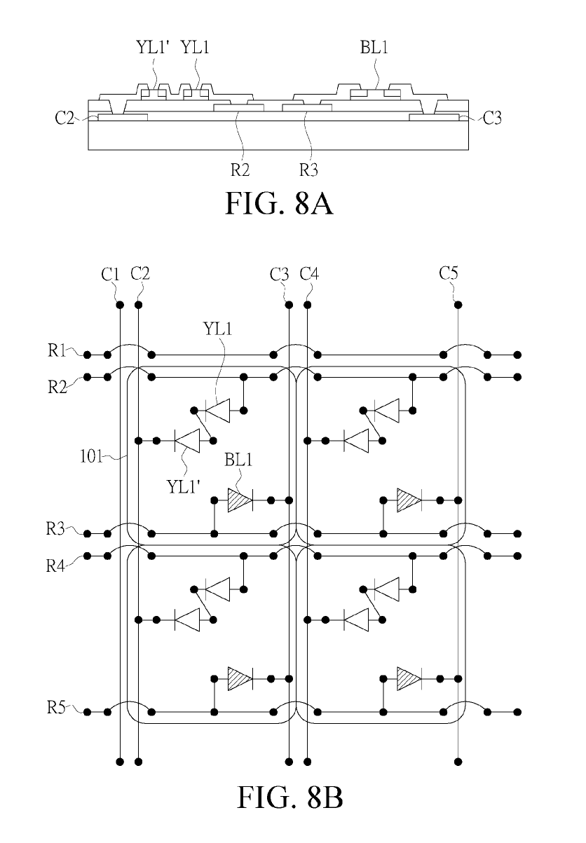

FIG. 8A is a schematic diagram of a pixel structure according to an embodiment of the present disclosure, and FIG. 8B is a circuit diagram corresponding to FIG. 8A. In this embodiment, the first sub-pixel 101 further includes a first auxiliary yellow LED YL1′, and a cathode end of a first yellow LED YL1 is coupled to an anode end of the first auxiliary yellow LED YL1′. That is, the first yellow LED YL1 is connected in series to the first auxiliary yellow LED YL1′.

In this embodiment, the first yellow LED YL1 and a first blue LED BL1 are respectively independently controlled, and driving currents of them can be respectively adjusted. Specifically, an anode end of the first yellow LED YL1 is coupled to a row electrode signal line R2, a cathode end of the first auxiliary yellow LED YL1′ is coupled to a column electrode signal line C2, an anode end of a first blue LED BL1 is coupled to a row electrode signal line R3, and a cathode end of the first blue LED BL1 is coupled to a column electrode signal line C3.

Driving currents provided by four control signals (e.g. the row electrode signal line R2, the row electrode signal line R3, the column electrode signal line C2, and the column electrode signal line C3) should enable an optical wavelength emitted by the first blue LED BL1 to shift towards a short wavelength when an optical wavelength emitted by the first yellow LED YL1 shifts towards the short wavelength. For example, if according to the attributes of the selected semiconductor materials, the first yellow LED YL1 shifts towards the short wavelength with the decrease of the current and the first blue LED BL1 shifts towards the short wavelength with the increase of the current, when the driving current provided to the first blue LED BL1 increases, the driving current provided to the first yellow LED YL1 should decrease, so that the first yellow LED YL1 and the first blue LED BL1 both present the phenomenon of shifting towards the short wavelength. However, because the driving current of the first yellow LED YL1 decreases for the moment, the light emitting strength may possibly become weak. To respond to the decreasing driving current and keep proper brightness of a sub-pixel, in this embodiment, the first auxiliary yellow LED YL1′ may be connected in series. Substantially same driving currents pass the first auxiliary yellow LED YL1′ and the first yellow LED YL1. By adding the first auxiliary yellow LED YL1′, the brightness reduced due to decrease of the driving current can be compensated, so that the first sub-pixel 101 keeps proper brightness on the whole.

FIG. 8A and FIG. 8B show an embodiment in which two yellow LEDs are connected in series. In another embodiment, the first sub-pixel 101 may alternatively include two blue LEDs connected in series, and the operating principle is similar to the foregoing description, and details are not described herein again.

In another embodiment, the first sub-pixel 101 may include a first yellow LED YL1 and a first auxiliary yellow LED YL1′ that are connected in parallel. Specifically, an anode end of the first yellow LED YL1 is coupled to an anode end of the first auxiliary yellow LED YL1′, and a cathode end of the first yellow LED YL1 is coupled to a cathode end of the first auxiliary yellow LED YL1′. The display brightness may also be improved by means of the first yellow LED YL1 and the first auxiliary yellow LED YL1′ that are connected in parallel, to respond to the decreasing driving current and keep proper brightness of a sub-pixel. In addition, the advantage of the structure that the first yellow LED YL1 is connected in parallel to the first auxiliary yellow LED YL1′ is: when one of the LEDs (such as the first yellow LED YL1) is broken, the other LED (such as the first auxiliary yellow LED YL1′) still can emit light by using current, so that the first sub-pixel 101 still can display image data.

The foregoing is an embodiment in which two yellow LEDs are connection in parallel. In another embodiment, the first sub-pixel 101 may alternatively include two blue LEDs connected in parallel, and the operating principle thereof is similar to the foregoing description, and can also achieve the advantage of improving the brightness and fault tolerance, and details are not described herein again.

In the pixel structure according to the foregoing embodiments, a sub-pixel uses a yellow LED and a blue LED, and when a light ray emitted by the yellow LED shifts towards a short wavelength, a light ray emitted by the blue LED shifts towards the short wavelength, so that stable white light can be generated by means of mixture, thereby mitigating the problem of color cast of the LEDs.

Based on the above, the present disclosure is disclosed through the foregoing embodiments; however, these embodiments are not intended to limit the present disclosure. A person of ordinary skill in the technical field to which the present disclosure belongs can make various changes and modifications without departing from the spirit and scope of the present disclosure. Therefore, the protection scope of the present disclosure is subject to the appended claims.

What is claimed is:

1. A pixel structure, comprising:
a first sub-pixel, wherein the first sub-pixel comprises:
a first yellow light emitting diode (LED);
a first blue LED; and
a first color filter, disposed above the first yellow LED and the first blue LED, wherein the first color filter allows a first color light with a first color to pass through.

2. The pixel structure according to claim 1, wherein when a first optical wavelength emitted by the first yellow LED shifts towards a short wavelength, a second optical wavelength emitted by the first blue LED shifts towards the short wavelength.

3. The pixel structure according to claim 1, wherein a yellow anode end and a yellow cathode end of the first yellow LED are respectively coupled to a first signal line and a second signal line, and a blue anode end and a blue cathode end of the first blue LED are respectively coupled to a third signal line and a fourth signal line.

4. The pixel structure according to claim 1, wherein yellow anode end and a yellow cathode end of the first yellow LED are respectively coupled to a first signal line and a second signal line, and a blue anode end and a blue cathode end of the first blue LED are respectively coupled to a third signal line and the second signal line.

5. The pixel structure according to claim 1, wherein the first yellow LED is connected in series to the first blue LED.

6. The pixel structure according to claim 1, wherein a yellow cathode end of the first yellow LED and a blue cathode end of the first blue LED are both coupled to a first signal line, and a yellow anode end of the first yellow LED and a blue anode end of the first blue LED are both coupled to a second signal line.

7. The pixel structure according to claim 1, wherein the first sub-pixel further comprises a first auxiliary yellow LED, and a yellow cathode end of the first yellow LED is coupled to an auxiliary anode end of the first auxiliary yellow LED.

8. The pixel structure according to claim 7, wherein a yellow anode end of the first yellow LED is coupled to a first signal line, an auxiliary cathode end of the first auxiliary yellow LED is coupled to a second signal line, and a blue anode end and a blue cathode end of the first blue LED are respectively coupled to a third signal line and a fourth signal line.

9. The pixel structure according to claim 1, wherein the first sub-pixel further comprises a first auxiliary yellow LED, a yellow anode end of the first yellow LED is coupled to an auxiliary anode end of the first auxiliary yellow LED, and a yellow cathode end of the first yellow LED is coupled to an auxiliary cathode end of the first auxiliary yellow LED.

10. The pixel structure according to claim 1, further comprising a second sub-pixel, wherein the second sub-pixel comprises:
a second yellow LED;
a second blue LED; and
a second color filter, disposed above the second yellow LED and the second blue LED, wherein the second color filter allows a second color light with a second color to pass through, and the second color is different from the first color.

11. The pixel structure according to claim 10, wherein a first anode end of the first blue LED is coupled to a second anode end of the second blue LED.

12. The pixel structure according to claim 10, further comprising a third sub-pixel, wherein the third sub-pixel comprises:
a third yellow LED;
a third blue LED; and
a third color filter, disposed above the third yellow LED and the third blue LED, wherein the third color filter allows a third color light with a third color to pass through, and the first color, the second color, and the third color are different.

13. The pixel structure according to claim 10, further comprising a third sub-pixel, wherein the third sub-pixel comprises:
a third blue LED.
